(19) United States
(12) Patent Application Publication
(10) Pub. No.: US 2014/0217400 A1
(43) Pub. Date: Aug. 7, 2014

(54) SEMICONDUCTOR ELEMENT STRUCTURE AND MANUFACTURING METHOD FOR THE SAME

(71) Applicant: Industrial Technology Research Institute, Hsinchu (TW)

(72) Inventors: Jing-Yi YAN, Zhubei City (TW); Chu-Yin HUNG, Hsinchu City (TW); Liang-Hsiang CHEN, Taichung City (TW); Hsiao-Chiang YAO, Koahsiung City (TW); Wu-Wei TSAI, Pingzhen City (TW)

(73) Assignee: Industrial Technology Research Institute, Hsinchu (TW)

(21) Appl. No.: 14/169,596

(22) Filed: Jan. 31, 2014

(30) Foreign Application Priority Data
Feb. 5, 2013 (TW) 102104336

(51) Int. Cl. H01L 29/786; H01L 29/66

(52) U.S. Cl. CPC H01L 29/78606; H01L 29/7869; H01L 29/66969
USPC 257/43; 438/104

(57) ABSTRACT

A semiconductor element structure and a manufacturing method for the same are provided. The semiconductor element structure may comprise a gate electrode, a dielectric layer, an active layer, a source, a drain and a protective layer. The active layer and the gate electrode are disposed on opposing sides of the dielectric layer. The source is disposed on the active layer. The drain is disposed on the active layer. The protective layer is disposed on the active layer. The protective layer may have a hydrogen content less than or equal to 0.1 at % and a sheet resistance higher than or equal to 10̂ 10 Ohm/sq.

This application claims the benefit of Taiwan application Serial No. 102104336, filed Feb. 5, 2013, the disclosure of which is incorporated by reference herein in its entirety.

### TECHNICAL FIELD

The disclosure relates in general to an oxide semiconductor element structure and a manufacturing method for the same, and relates to a semiconductor element structure having a channel protective layer or a semiconductor etching barrier layer and a manufacturing method for the same.

### BACKGROUND

An oxide transistor element currently available, having superior element characteristics and uniformity and applicable to large area and low temperature process, and has manufacturers' great interest in related research. Although the oxide transistor has superior element characteristics, its material system is affected by external environment and the manufacturing process. Therefore, a structure providing enhanced element characteristics and stability and a process for manufacturing the same are a prominent task for the manufacturers.

### SUMMARY

The disclosure is related to an oxide semiconductor element structure and a manufacturing method for the same. The semiconductor element or array structure has stable electrical characteristics and superior operating efficiency.

According to one embodiment, a semiconductor element structure is provided. The semiconductor element structure comprises a gate electrode, a dielectric layer, an active layer, a source, a drain and a protective layer. The active layer and the gate electrode are disposed on opposing sides of the dielectric layer. The source is disposed on the active layer. The drain is disposed on the active layer. The protective layer is disposed on the active layer. The protective layer has a hydrogen content less than or equal to 0.1 at % and a sheet resistance higher than or equal to 10̂ 10 Ohm/sq.

According to another embodiment, a semiconductor element structure is provided. The semiconductor element structure comprises a gate electrode, a dielectric layer, an active layer, a source, a drain and a protective layer. The active layer and the gate electrode are disposed on opposing sides of the dielectric layer. The source is disposed on the active layer. The drain is disposed on the active layer. The protective layer is disposed on the active layer. The protective layer has a hydrogen content less than or equal to 0.1 at % and a sheet resistance higher than or equal to 10̂ 10 Ohm/sq. The protective layer comprises NbOₓ, wherein 2.4<x<5.

According to an alternative embodiment, a manufacturing method of a semiconductor element structure is provided. The method comprises the following steps. A gate electrode is formed. A dielectric layer is formed. An active layer is formed. The active layer and the gate electrode are disposed on opposing sides of the dielectric layer. A source is formed on the active layer. A drain is formed on the active layer. A protective layer is formed on the active layer. The protective layer has a hydrogen content less than or equal to 0.1 at % and a sheet resistance higher than or equal to 10̂ 10 Ohm/sq.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1 shows a cross-sectional view of a semiconductor element structure according to an embodiment;

FIG. 2 shows a cross-sectional view of a semiconductor element structure according to an embodiment;

FIG. 3 shows a cross-sectional view of a semiconductor element structure according to an embodiment;

FIG. 4 shows a cross-sectional view of a semiconductor element structure according to an embodiment;

FIG. 5 shows a cross-sectional view of a semiconductor element structure according to an embodiment;

FIG. 6 shows a diagram of electrical characteristic curves of a semiconductor element structure according to an embodiment and a comparison example;

FIG. 7 shows a diagram of electrical characteristic curves of a semiconductor element structure according to an embodiment

FIG. 8 shows a diagram of electrical characteristic curves of a semiconductor element structure a comparison example;

FIG. 9 shows a diagram of electrical characteristic curves of a semiconductor element structure according to an embodiment and a comparison example;

FIG. 10 shows an AEI image of a patterned film according to embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

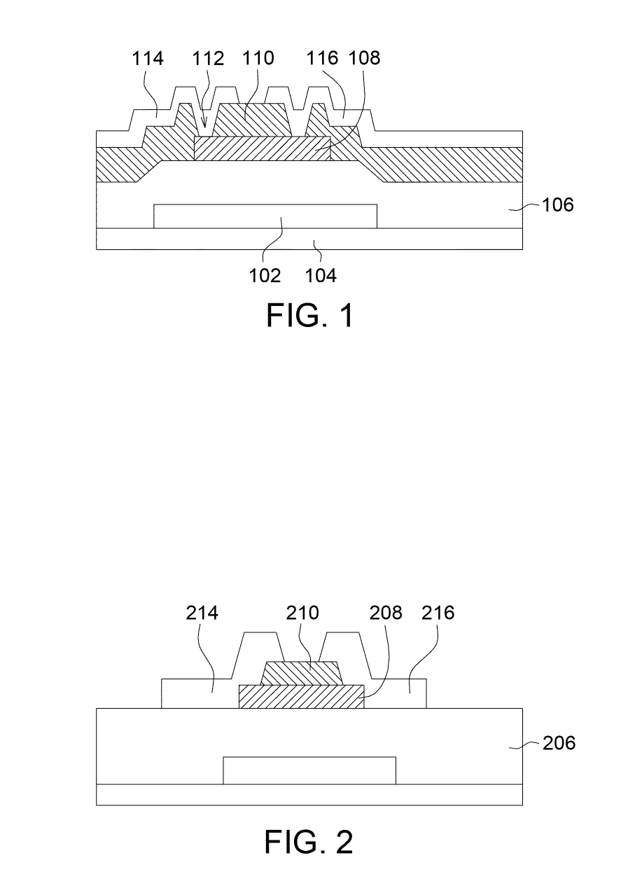

FIG. 1 shows a cross-sectional view of a semiconductor element structure according to an embodiment. An electrode layer 102 is formed on a substrate 104. The substrate 104 may comprise a Si substrate, a glass substrate, a polymer substrate or a metal foil. The substrate may be covered by a flat layer or an insulating layer, having silicon oxide, silicon nitride, an organic material such as polyimide, a spin-on-glass (SOG) material, or a combination thereof. The electrode layer 102 (such as a gate) may comprise aluminum (Al), titanium (Ti), molybdenum (Mo), AlNd, MoW, a combination thereof, or a conductive material. A dielectric layer 106 is formed on the electrode layer 102 and the substrate 104. The dielectric layer 106 may comprise an oxide or a nitride, such as silicon oxide, silicon nitride, or silicon oxynitride, or other suitable materials, whose leakage current density is less than 10⁻⁷ A/cm² under a 1 MV/cm electrical field. For example, the dielectric layer 106 may be formed by a chemical vapor deposition method, a physical vapor deposition method, a solution process method such as a spin-coating method, or other suitable methods.

An active layer 108 is formed on the dielectric layer 106. The active layer 108 may comprise a Si-based material, an organic semiconductor, an oxide semiconductor, or a combination thereof. The active layer 108 comprises indium gallium zinc oxide (InGaZnO; IGZO), aluminum tin and zinc oxide (AISnZnO; ATZO), indium oxide (InOₓ), gallium oxide (GaOₓ), tin oxide (SnOₓ), zinc oxide (ZnO) or a combination thereof. In an embodiment, the active layer 108 comprises InₓZn_{y}Sn_{z}O, wherein 0.2≦x/(x+y+z)≦0.6, 0.15≦y/(x+y+z)≦0.35, 0.2≦z/(x+y+z)≦0.5 x, y, z represent atomic ratios (at %). These conditions help to increase the electrical characteristics and operating efficiency of the semiconductor element structure. For example, the active layer 108 may be formed by patterning a semiconductor film after the semiconductor film is formed. The semiconductor film may be formed by a chemical vapor deposition method, a physical vapor deposition method, or other suitable methods. The patterning method comprises a photolithographic etching process, but is not limited thereto.

A protective layer 110 may be formed on the active layer 108 or the dielectric layer 106. In an embodiment, the protective layer 110 physically contacts the active layer 108. The protective layer 110 may have an opening 112 exposing the active layer 108. In an embodiment, the protective layer 110 which physically contacts the active layer 108 can protect semiconductor elements from being affected by external water/oxygen, atmosphere or environment factors during the manufacturing process, such that the characteristics of the semiconductor element structure can be improved.

In an embodiment, the protective layer 110 has a hydrogen content less than or equal to 0.1 at % and a sheet resistance higher than or equal to 10̂10 Ohm/sq. For example, the sheet resistance is 10̂10 Ohm/sq−10̂14 Ohm/sq or higher than 10̂14 Ohm/sq. The protective layer 110 may comprise an oxide, a nitride or a carbide of IIA-IVA, IIIB-VIIB elements, or a combination thereof. The protective layer 110 may comprise an oxide, a nitride or a carbide of silicon (Si), titanium (Ti), aluminum (Al), niobium (Nb), tantalum (Ta), hafnium (Hf), vanadium (V), yttrium (Y), molybdenum (Mo), manganese (Mn), tin (Sn) or calcium (Ca), or a combination thereof. The protective layer 110 may comprise an oxide of niobium (Nb). The protective layer 110 may comprise NbOₓ, NbₓTi_{y}O, NbₓSi_{y}O, or a combination thereof. NbOₓ satisfies a condition: 2.4<x<5. NbₓTi_{y}O satisfies conditions: 0<x/(x+y)<1, 0<y/(x+y)<1. NbₓSi_{y}O satisfies conditions: 0<x/(x+y)<1, 0<y/(x+y)<1. Besides, the protective layer 110 may be formed by TiₓMn_{y}O or TiₓAl_{y}O, and as the material satisfies conditions: 0<x/(x+y)<1, 0<y/(x+y)<1, it can help to increase the electrical characteristics and operating efficiency of the semiconductor element structure. In an embodiment, the protective layer 110 is formed by patterning a film formed by using a DC sputtering process. For example, the sputtering process uses 1 kW-3 kW DC power, 50 sccm-200 sccm argon (Ar), 0 sccm-50 sccm oxygen (O₂) and a sputtering target material. The sputtering target material may have a resistivity of 0.1 Ω-cm˜0.000005 Ω-cm. The sputtering target material may comprise NbOₓ, NbₓTi_{y}O, NbₓSi_{y}O, a combination thereof, or a material system of TiₓMn_{y} or TiₓAl_{y}. NbOₓ satisfies a condition: 2.4<x<5. NbₓTi_{y}O satisfies conditions: 0<x/(x+y)<1, 0<y/(x+y)<1. NbₓSi_{y}O satisfies conditions: 0<x/(x+y)<1, 0<y/(x+y)<1. TiₓMn_{y} satisfies conditions: 0<x/(x+y)<1, 0<y/(x+y)<1. TiₓAl_{y} satisfies conditions: 0<x/(x+y)<1, 0<y/(x+y)<1. These conditions help to improve the electrical characteristics and operating efficiency of the semiconductor element structure. The method for patterning a film comprises photolithographic etching process but the present disclosure is not limited thereto. In an embodiment, the protective layer 110 has an advantage of being able to be patterned easily and thus can be patterned to a fine and precise feature. The method for forming the protective layer 110 is simple and stable, and is easy to control. In an embodiment, the protective layer 110 is formed by using the DC sputtering process. Quality of the coated protective layer 110 would be stable since the target material is not affected by a shift of the DC sputtering process. Since it is easier to sputter a large-sized target material by the direct current (DC) or alternating current (AC) sputtering process than in the radio frequency (RF) sputtering process, the industries are more interested in the development of the DC or AC sputtering process than in the RF sputtering process. The DC or AC sputtering process may be subjected to the resistivity of the sputtering target material. Normally, the resistance of the sputtering target material resistance is not higher than 0.5 Ω-cm, otherwise quality as well as the conformity and yield of the process film may be affected. The sputtering process can effectively reduce the hydrogen content of the process film to be lower than 0.1 at % without affecting the characteristics of the oxide semiconductor element.

A first conductive element 114 (one of the source and the drain) and a second conductive element 116 (the other of the drain and the source) are disposed in the opening 112 of the protective layer 110 and coupled to the active layer 108. The first conductive element 114 and the second conductive element 116 may be extended to an upper surface of the protective layer 110. The first conductive element 114 and the second conductive element 116 may comprise a metal such as copper, gold, silver, or other suitable materials. In an embodiment, the first conductive element 114 and the second conductive element 116 may be formed by patterning a conductive film after the conductive film is formed. The conductive film may be formed by a deposition method such as chemical vapor deposition method, a physical vapor deposition method, or other suitable methods. The patterning method comprises photolithographic etching process, but the present disclosure is not limited thereto.

In an embodiment, the semiconductor element structure of FIG. 1 is a lower gate transistor. The electrode layer 102 is used as a gate electrode. The dielectric layer 106 is used as a gate dielectric layer. The first conductive element 114 and the second conductive element 116 are respectively used as a source conductive element and a drain conductive element.

In an embodiment, the selected material and formation method of the elements provide superior electrical characteristics and stable operation for the semiconductor element structure.

FIG. 2 shows a cross-sectional view of a semiconductor element structure according to an embodiment. The semiconductor element structure of FIG. 2 is different from the semiconductor element structure of FIG. 1 in that a protective layer 210 is formed on an active layer 208. A first conductive element 214 and a second conductive element 216 are formed on two sides of the protective layer 210 and the active layer 208, and are extended on at least at least a part of an upper surface of a dielectric layer 206.

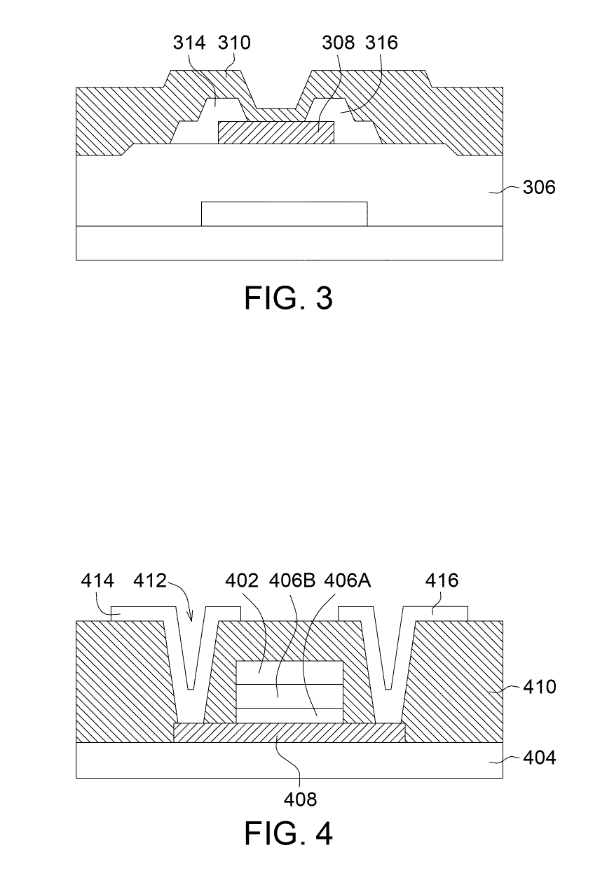

FIG. 3 shows a cross-sectional view of a semiconductor element structure according to an embodiment. The semiconductor element structure of FIG. 3 is different from the semiconductor element structure of FIG. 1 in that a first conductive element 314 and a second conductive element 316 are formed on two sides of an active layer 308, and are extended on at least a part of an upper surface of a dielectric layer 306. A protective layer 310 is formed on the active layer 308 between the first conductive element 314 and the second conductive element 316, and is extended on the first conductive element 314, the second conductive element 316 and the dielectric layer 306.

In an embodiment of the disclosure, the protective layer 310 may be a single-layer film, or a stacking structure having two or more than two layers. Besides the inorganic material system mentioned above, an organic material, an organic-inorganic mixed material, a sol-gel material system or a spin-on-glass (SOG) material system may be used. In the embodiment of the protective layer 310 formed by a multi-layer stacking structure, the first protective layer (or a portion of the protective layer 310 contacting with the active layer 308) contacting the active layer 308 (or semiconductor layer) can be realized by an inorganic film of an oxide, a nitride, or a carbide formed by using the DC or AC sputtering process, and have the sheet resistance higher than 1×10̂10 ohm/sq. If the protective layer 310 is realized by a multi-layer structure, the method for manufacturing a portion of the protective layer 310 not contacting with the active layer 308 comprises, a chemical vapor deposition (CVD) method, a physical vapor deposition (PVD) method, or a spin-coating method, but is not limited thereto.

FIG. 4 shows a cross-sectional view of an upper gate semiconductor element structure according to an embodiment. The semiconductor element structure of FIG. 4 is different from the semiconductor element structure of FIG. 1 in that an active layer 408 is formed on a substrate 404. A protective layer 406A and a dielectric layer 406B are formed on the active layer 408. A electrode layer 402 for a gate is formed on the dielectric layer 406B. A flat layer 410 is formed on the active layer 408, the substrate 404, and a stacking structure composed of the protective layer 406A, the dielectric layer 406B and the electrode layer 402. The flat layer 410 has an opening 412 exposing the active layer 408. In an embodiment, the first conductive element 414 and the second conductive element 416 are formed in the opening 412 of the flat layer 410 and coupled to the active layer 408. In another embodiment, the first conductive element 414 and the second conductive element 416 may be extended on at least a part of an upper surface of the flat layer 410.

The active layer 408 may comprise an Si-based material, an organic semiconductor, an oxide semiconductor, or a combination thereof. The active layer 408 comprises indium gallium zinc oxide (InGaZnO; IGZO), aluminum tin and zinc oxide (AISnZnO; ATZO), indium oxide (InOₓ), gallium oxide (GaOₓ), tin oxide (SnOₓ), zinc oxide (ZnO) or a combination thereof. In an embodiment, the active layer 408 comprises InₓZn_{y}Sn_{z}O, wherein the conditions 0.2≦x/(x+y+z)≦0.6, 0.15≦y/(x+y+z)≦0.35, and 0.2≦z/(x+y+z)≦0.5 help to improve the electrical characteristics and operating efficiency of the semiconductor element structure.

In an embodiment, the protective layer 406A physically contacts the active layer 408. The protective layer 406A protects other elements from being affected by from being affected by external water/oxygen, atmosphere or environment factors during the manufacturing process, such that the characteristics of the semiconductor element structure can be improved. In the present embodiment, the protective layer 406A may have the characteristics of dielectric material. The protective layer 406A may comprise an oxide, a nitride or a carbide of IIA-IVA, IIIB-VIIB elements, or a combination thereof. The protective layer 406A may comprise an oxide, a nitride or a carbide of silicon (Si), titanium (Ti), aluminum (Al), niobium (Nb), tantalum (Ta), hafnium (Hf), vanadium (V), yttrium (Y), molybdenum (Mo), manganese (Mn), tin (Sn) or calcium (Ca), or a combination thereof. The protective layer 406A may comprise an oxide of niobium (Nb). The protective layer 406A may comprise NbOₓ, NbₓTi_{y}O, NbₓSi_{y}O, or a combination thereof. NbOₓ satisfies a condition: 2.4<x<5. NbₓTi_{y}O satisfies conditions: 0<x/(x+y)<1, 0<y/(x+y)<1. NbₓSi_{y}O satisfies conditions: 0<x/(x+y)<1, 0<y/(x+y)<1. Besides, the protective layer 406A may be formed by TiₓMn_{y}O or TiₓAl_{y}O, and as the material satisfies conditions: 0<x/(x+y)<1, 0<y/(x+y)<1. Those conditions can help to increase the electrical characteristics and operating efficiency of the semiconductor element structure. In an embodiment, the protective layer 406A is formed by patterning a film formed by using a DC sputtering process. For example, the sputtering process uses 1 kW-3 kW DC power, 50 sccm-200 sccm argon (Ar), 0 sccm-50 sccm oxygen (O₂) and a sputtering target material. The sputtering target material may have a resistivity of 0.1 Ω-cm˜0.000005 Ω-cm. The sputtering target material may comprise NbOₓ, NbₓTi_{y}O, NbₓSi_{y}O, a combination thereof, or a material system of TiₓMn_{y} or TiₓAl_{y}. NbOₓ satisfies a condition: 2.4<x<5. NbₓTi_{y}O satisfies conditions: 0<x/(x+y)<1, 0<y/(x+y)<1. NbₓSi_{y}O satisfies conditions: 0<x/(x+y)<1, 0<y/(x+y)<1. TiₓMn_{y} satisfies conditions: 0<x/(x₊y)<1, 0<y/(x₊y)<1. TiₓAl_{y} satisfies conditions: 0<x/(x₊y)<1, 0<y/(x₊y)<1. These conditions help to improve the electrical characteristics and operating efficiency of the semiconductor element structure. The method for patterning a film comprises photolithographic etching process but the present disclosure is not limited thereto. In an embodiment, the protective layer 406A has an advantage of being able to be patterned easily and thus can be patterned to a fine and precise feature. The method for forming the protective layer 406A is simple and stable, and is easy to control. In an embodiment, the protective layer 406A is formed by using the DC sputtering process. Quality of the coated protective layer 406A would be stable since the target material is not affected by a shift of the DC sputtering process. Moreover, the sputtering process can effectively reduce the hydrogen content of the process film to be lower than 0.1 at %, and thus characteristics of the oxide semiconductor element would not be affected by it and the semiconductor element structure has stable and outstanding operating efficiency.

In an embodiment, the semiconductor element structure of FIG. 4 is an upper gate transistor. The electrode layer 402 is used as a gate electrode.

The protective layer 406A and the dielectric layer 406B are used as a gate dielectric layer. The first conductive element 414 and the second conductive element 416 are respectively used as a source conductive element and a drain conductive element.

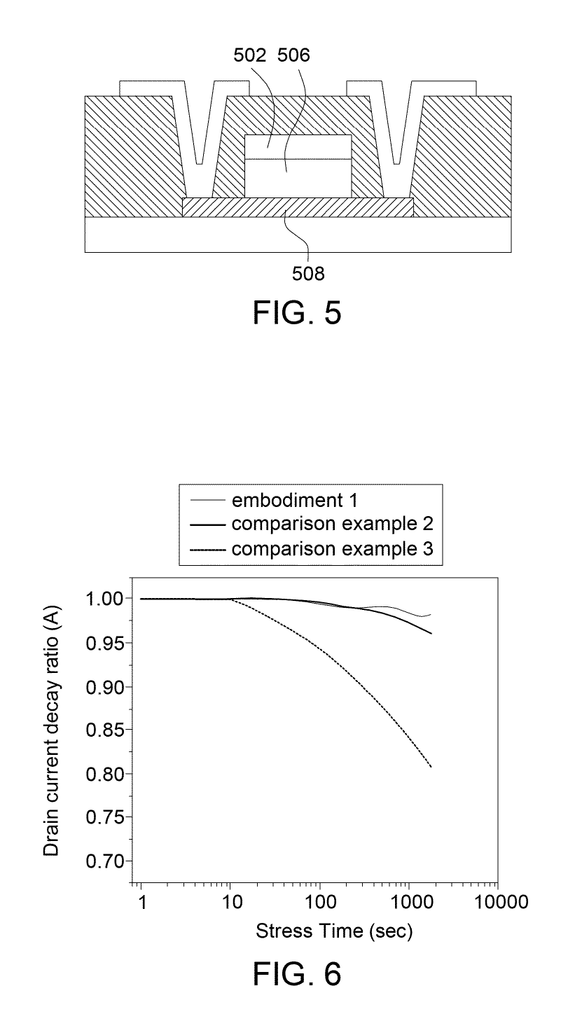

FIG. 5 shows a cross-sectional view of a semiconductor element structure according to an embodiment. The semiconductor element structure of FIG. 5 is different from the semiconductor element structure of FIG. 4 in that a protective layer 506 is disposed between the active layer 508 and the electrode layer 502 and at the same time has the characteristics of a dielectric layer.

FIG. 6 shows a diagram of electrical characteristic curves of a semiconductor element structure according to embodiment 1, comparison example 2, and comparison example 3. Embodiment 1, comparison example 2 and comparison example 3 have the same active layer which is formed by indium gallium zinc oxide (IGZO), wherein the proportion of elements for indium (In): gallium (Ga): zinc (Zn) is about 1:1:1. In embodiment 1, niobium oxide (NbOₓ) is formed by using the DC sputtering process and used as a protective layer. In comparison example 2, an SiO₂ film formed by using the plasma-enhanced chemical vapor deposition (PECVD) process is used as a protective layer. In comparison example 3, no protective layer is used. The long-term stress test (LTS) compares the delay of output current in 1800 seconds in each embodiment and comparison example under the conditions that the gate voltage is 20V and the initial output current is 80 uA. As illustrated in the results of FIG. 6, the current decay is less than 2% in embodiment 1, about 5% in comparison example 2, and larger than 20% in comparison example 3. The semiconductor element structure of the embodiment 1 has superior operating efficiency and stability.

In comparison example 2, a SiO₂ film formed by using the PECVD process is used as a protective layer. During the PECVD process of forming an SiO₂ protective layer, the hydrogen plasma generated by the reaction gas makes the hydrogen atoms or ions diffuse and generate defects in the oxide semiconductor. As a result, the oxide semiconductor may be unstable in the long-term stress test, and such defects can hardly be improved in the subsequent tempering process. The excessive hydrogen content generated during the manufacturing process will make the oxide semiconductor be doped with excessive hydrogen atoms or ions, such that the oxide semiconductor film will change its characteristics from being a semiconductor, to a near conductor, and the oxide thin film transistor element will be incapacitated. Therefore, the PECVD process of forming a SiO₂ protective layer has a narrow range of parameters, and it is not easy to keep the device quality stable. In general, the SiO₂ film formed by using the PECVD process and used as a protective layer has a hydrogen content about 1-4 at. %. In embodiment 1, the protective layer, formed by using the sputtering process and having a hydrogen content less than or equal to 0.1 at %, protects the semiconductor element and has a reduced influence on the characteristics of the oxide semiconductor. In comparison example 3, since the oxide semiconductor element not covered by any protective layers reacts with the water vapor, oxygen and hydrogen during the long-term stress test and become defected, element characteristics decay fast.

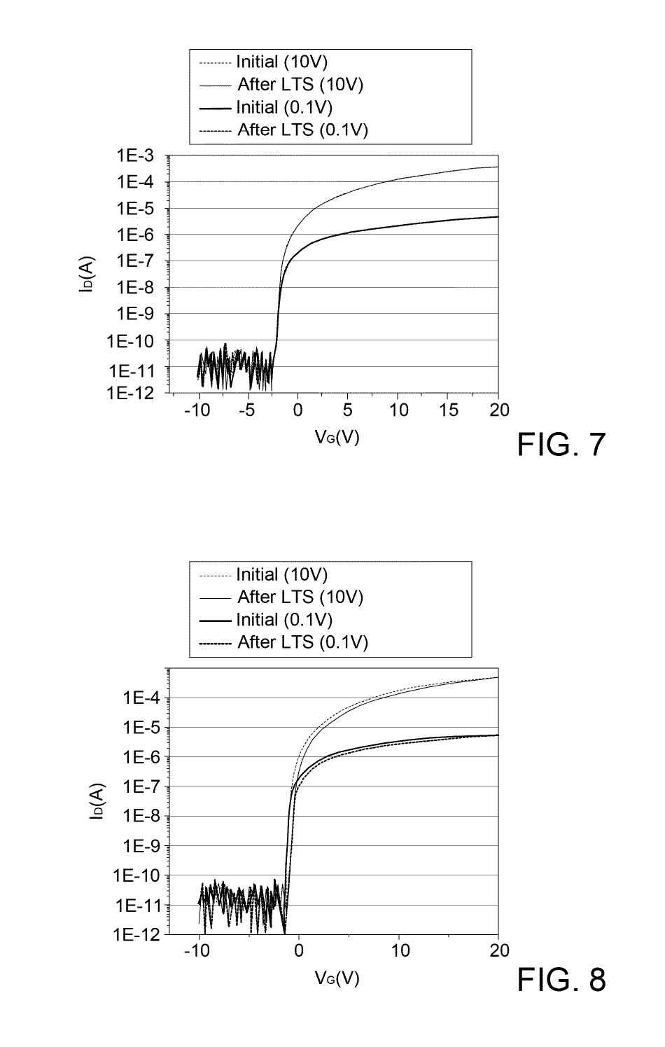

FIG. 7 and FIG. 8 are diagrams of Id-Vg curves of a semiconductor element structure before and after the long-term stress test according to embodiment 1 and comparison example 2 respectively. The voltage Vt of the semiconductor element structure of FIG. 7 according to embodiment 1 drifts by about 0.08V, which is less than the voltage Vt of the semiconductor element structure of FIG. 8 according to comparison example 2 which drifts by about 0.4V. A comparison between FIGS. 7 and 8 shows that the protective layer formed by using the sputtering process according to embodiment 1 provides better protection to the oxide semiconductor than the SiO₂ protective layer formed by using the PECVD process according to comparison example 2.

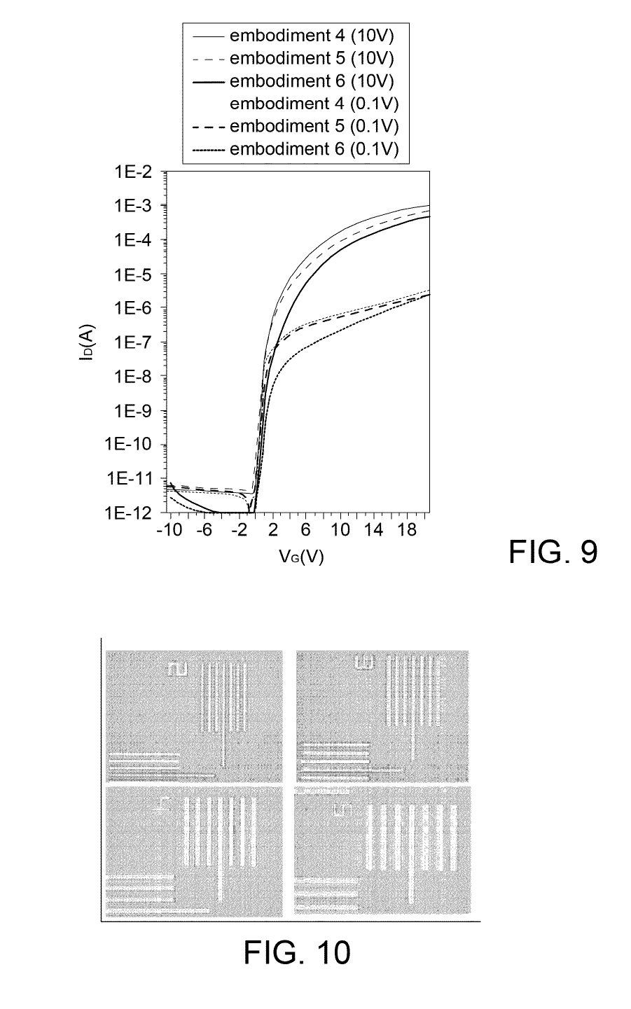

FIG. 9 shows a diagram of Id-Vg curves of a semiconductor element structure according to embodiment 4, embodiment 5, and comparison example 6. In embodiment 4, the active layer formed by InₓZn_{y}Sn_{z}O satisfies the conditions: x=0.33, y=0.19, z=0.48. In embodiment 5, the active layer formed by InₓZn_{y}Sn_{z}O satisfies the conditions: x=0.4, y=0.22, z=0.38. In comparison example 6, the active layer is formed by a normal IGZO (1114). The proportion of elements for InSnZnO used in embodiments 4 and 5 is provided by the present disclosure, while IGZO used in comparison example 6 is based on an ordinary proportion of elements. To have an objective comparison between the characteristics of different oxide semiconductor elements, the three oxide semiconductor elements of embodiment 4, embodiment 5 and comparison example 6 have different semiconductor layers in terms of their constituting elements but use the same DC sputtering process and the same structure of FIG. 1 of the present disclosure. The aluminum-titanium stacking film is used for forming a gate, a source and a drain electrode. The gate dielectric layer is realized by an SiO₂ film formed by using the PECVD process. The protective layer is formed by niobium oxide (NbOₓ) by using the sputtering process. The comparison of the three oxide thin film transistor elements of FIG. 9 shows that embodiment 4 has best element characteristics, the InₓZn_{y}Sn_{z}O system used in embodiments 4 and 5 has better performance than the commonly used IGZO system, and the electron mobility of the InₓZn_{y}Sn_{z}O system is at least 1.5 times larger than that of the IGZO system.

In the embodiments illustrated in FIGS. 1-5, a channel length of a thin film transistor element is controlled by the patterning ability of the protective layer. Given that the channel width of an element is fixed, the element whose channel length is shorter provides a larger output current and has a faster driving speed. FIG. 10 shows a verification of the patterning ability of the sputtering protective layer of the present disclosure. In the present embodiment, the verification is an image of the protective layer patterned by using the etching process. The image shows that the protective layer can accurately achieve even a 2 um pattern, and can meet the dimension need of channel length applicable to oxide thin film transistors currently available.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor element structure, comprising:
a gate electrode;
a dielectric layer;
an active layer, wherein the active layer and the gate electrode are disposed on opposing sides of the dielectric layer;
a source disposed on the active layer;
a drain disposed on the active layer; and
a protective layer disposed on the active layer, wherein the protective layer has a hydrogen content less than or equal to 0.1 at % and a sheet resistance higher than or equal to 10̂10 Ohm/sq.

2. A semiconductor element structure, comprising:
a gate electrode;
a dielectric layer;
an active layer, wherein the active layer and the gate electrode are disposed on opposing sides of the dielectric layer;
a source disposed on the active layer;
a drain disposed on the active layer; and
a protective layer disposed on the active layer, wherein the protective layer has a hydrogen content less than or equal to 0.1 at % and a sheet resistance higher than or equal to 10̂10 Ohm/sq, and the protective layer at least comprises NbOₓ, 2.4<x<5.

3. The semiconductor element structure according to claims 1, wherein the protective layer has a single-layer or multi-layer structure.

4. The semiconductor element structure according to claims 1, wherein the protective layer comprises an inorganic material, an organic material, or a combination thereof.

5. The semiconductor element structure according to claims 1 wherein a portion of the protective layer contacting with the active layer is formed by an inorganic material.

6. The semiconductor element structure according to claims 1, wherein the protective layer is formed by a sputtering method.

7. The semiconductor element structure according to claim 6, wherein a target material for the protective layer used in the sputtering method has a resistivity of 0.1−5×10̂⁻⁶ ohm-cm.

8. The semiconductor element structure according to claims 1, wherein the protective layer is a multi-layer structure, and a portion of the protective layer not contacting with the active layer is formed by a method comprising a chemical vapor deposition (CVD) method, a physical vapor deposition (PVD) method, or a solution process method.

9. The semiconductor element structure according to claims 1, wherein the protective layer comprises NbOₓ, NbₓTi_{y}O, NbₓSi_{y}O, or a combination thereof, NbOₓ satisfies a condition: 2.4<x<5, and NbₓTi_{y}O and NbₓSi_{y}O satisfy conditions: 0<x/(x+y)<1, 0<y/(x+y)<1.

10. The semiconductor element structure according to claims 1, wherein the protective layer comprises TiₓMn_{y}O or TiₓAl_{y}O, satisfying conditions: 0<x/(x+y)<1, 0<y/(x+y)<1.

11. The semiconductor element structure according to claims 1, wherein the active layer comprises indium gallium zinc oxide (InGaZnO; IGZO), aluminum tin and zinc oxide (AISnZnO; ATZO), indium oxide (InOₓ), gallium oxide (GaOₓ), tin oxide (SnOₓ), zinc oxide (ZnO) or a combination thereof.

12. The semiconductor element structure according to claims 1, wherein the active layer comprises InₓZn_{y}Sn_{z}O satisfying conditions: 0.2≦x/(x+y+z)≦0.6, 0.15≦y/(x+y+z)≦.0.35, 0.2≦z/(x+y+z)≦0.5.

13. A manufacturing method of a semiconductor element structure, comprising:
forming a gate electrode;
forming a dielectric layer;
forming an active layer, wherein the active layer and the gate electrode are disposed on opposing sides of the dielectric layer;
forming a source on the active layer;
forming a drain on the active layer; and
forming a protective layer on the active layer, wherein the protective layer has a hydrogen content less than or equal to 0.1 at % and a sheet resistance higher than or equal to 10̂10 Ohm/sq.

14. The manufacturing method of the semiconductor element structure according to claim 13, wherein the protective layer has a single-layer or multi-layer structure.

15. The manufacturing method of the semiconductor element structure according to claim 13, wherein the protective layer comprises an inorganic material, an organic material, or a combination thereof.

16. The manufacturing method of the semiconductor element structure according to claim 13, wherein a portion of the protective layer contacting with the active layer is formed by an inorganic material.

17. The manufacturing method of the semiconductor element structure according to claim 13, wherein the protective layer is formed by a sputtering method.

18. The manufacturing method of the semiconductor element structure according to claim 17, wherein a target material for the protective layer used in the sputtering method has a resistivity of 0.1˜5×10̂−6 ohm-cm.

19. The manufacturing method of the semiconductor element structure according to claim 13, wherein the protective layer has a multi-layer structure, a portion of the protective layer not contacting with the active layer is formed by a method comprising a chemical vapor deposition (CVD) method, a physical vapor deposition (PVD) method, or a solution process method.

20. The manufacturing method of the semiconductor element structure according to claim 13, wherein the protective layer comprises NbOₓ, NbₓTi_{y}O, NbₓSi_{y}O, or a combination thereof, NbO_{X} satisfies a condition: 2.4<x<5, and NbₓTi_{y}O and NbₓSi_{y}O satisfy conditions: 0<x/(x+y)<1, 0<y/(x+y)<1.

21. The manufacturing method of the semiconductor element structure according to claim 13, wherein the protective layer comprises TiₓMn_{y}O or TiₓAl_{y}O, satisfying conditions: 0<x/(x+y)<1, 0<y/(x+y)<1.

22. The manufacturing method of the semiconductor element structure according to claim 13, wherein the active layer comprises indium gallium zinc oxide (InGaZnO; IGZO), aluminum tin and zinc oxide (AlSnZnO; ATZO), indium oxide (InOₓ), gallium oxide (GaOₓ), tin oxide (SnOₓ), zinc oxide (ZnO) or a combination thereof.

23. The manufacturing method of the semiconductor element structure according to claim 13, wherein the active layer comprises InₓZn_{y}Sn_{z}O satisfying conditions: 0.2≦x/(x+y+z)≦0.6, 0.15≦y/(x+y+z) 0.2≦z/(x+y+z)≦0.5.
